(19) United States
(12) Patent Application Publication
(10) Pub. No.: US 2003/0017777 A1
(43) Pub. Date: Jan. 23, 2003

(54) Method for manufacturing electroluminescence display panel

(76) Inventors: Hideki Matsuoka, Gifu-shi (JP); Kiyoshi Yoneda, Motosu-gun (JP)

Correspondence Address: CANTOR COLBURN, LLP, 55 GRIFFIN ROAD SOUTH, BLOOMFIELD, CT, 06002

(21) Appl. No.: 10/185,544

(22) Filed: Jun. 28, 2002

(30) Foreign Application Priority Data
Jun. 29, 2001 (JP) 2001-198928

(51) Int. Cl. H01J 9/00

(52) U.S. Cl. 445/24

(57) ABSTRACT

A display substrate and a sealing member are affixed, an element formation surface of the display substrate having an electroluminescence element formed thereon and the sealing member having an adhesive applied thereon in advance on the side opposing the element formation surface of the display substrate. After the affixing process, pressure is applied to the adhesive which is applied in a manner to surround the element layer formation region of the display substrate by pressing the substrates, to deform the adhesive and to achieve a predetermined gap. The adhesive is irradiated with ultraviolet light and is cured, to adhere the substrates. During the application of the adhesive before adhering, an opening is formed in the application pattern of the adhesive in such a manner that the opening does not close by the application of pressure. After the substrates are adhered with a predetermined gap therebetween, the opening is closed to completely seal the element surface of the display substrate.

### BACKGROUND OF THE INVENTION

1. Field of the Invention

The present invention relates to a method for manufacturing an electroluminescence display panel used in a display device for displaying text, images, etc.

2. Description of the Related Art

In general, in an electroluminescence (EL) display panel constructed to include an EL element, an element surface of a display substrate onto which the EL element or the like is formed is sealed by a suitable sealing member because the characteristics of the EL element, which is the light emitting element of the display panel, are easily degraded by moisture, which, in turn, degrades the display panel functionality as a display device. Therefore, in order to maintain the display quality as an EL display panel for a long time, it is necessary to seal the EL element stably and at a high quality.

The display substrate is constructed to include an element layer in which a display element such as the EL element and a driving element for driving the EL element to emit light is layered on a glass substrate. When the display substrate (element substrate) is sealed with the sealing member, the element surface of the display substrate and the sealing member are affixed in an opposing manner with a predetermined gap in between. An adhesive is applied in advance on the surface to be affixed in a manner to surround the display region of the display substrate, and during affixing, the adhesive is cured.

FIG. 1 schematically shows a process in which a plurality of (twelve in the illustrated structure) display substrates 33 are formed on a glass substrate 31 in order to manufacture a plurality of (twelve) EL display panels simultaneously, and a sealing glass 34 which is a sealing member is affixed to the element surface. As shown in FIGS. 1(a) and 1(b), an adhesive 35 is applied on the sealing glass 34 in such a manner as to surround each display region of the display substrates 33. The adhesive 35 seals the contacting surfaces between the glass substrate 31 and the sealing glass 34 to thereby seal the element layer 32 formed on the element surface of the display substrate 33.

FIG. 2 schematically shows the cross section of the structure when the glass substrate 31 is affixed to the sealing glass 34. The glass substrate 31 is held to a supporting member 37 using vacuum suction and affixed to the sealing glass 34 which is placed on a base (not shown). During this process, as shown in FIG. 2, the glass substrate 31 and the sealing glass 34 are pressed towards each other so that a predetermined gap G is formed between the glass substrate 31 and the sealing glass 34. After the gap G is adjusted to the predetermined value, a curing process for the adhesive 35 is applied and the display substrate 33 is sealed by the sealing glass 34. During this sealing process, the width of the portion of the glass substrate 31 and of the sealing glass 34 in contact with the adhesive 35, that is, the seal line width W, is determined by the amount and viscosity of the adhesive 35, the gap G, the magnitude and duration of the applied pressure, etc. Also, a spacer 38 having a cylindrical or a spherical shape with a predetermined diameter, for example, is provided within the adhesive 35 (schematically shown in FIG. 2) so that a predetermined gap G can be obtained using the spacer 38 as a stopper for the pressure application.

Normally, a resinous adhesive is used as the adhesive 35. When a resinous adhesive is used, the material of the resin is selected based on the type of display substrate 33, the object of sealing, etc. However, for some of these resins, the viscosity cannot be adjusted.

Therefore, when the sealing process is performed using such a resin, it is necessary to press the substrates towards each other such that the gap G between the substrates reaches a target value and the seal line width W is stabilized.

When the glass substrate 31 and the sealing glass 34 are affixed with the adhesive in between and then the substrates are pressed towards each other as described above, the gas present in the atmosphere is sealed in the internal space to be sealed, under a pressurized condition. If the internal pressure of the internal space is significantly greater than the ambient pressure, the adhesive may detach or adhering defects may occur after sealing. As a solution, as shown in FIG. 3, for example, an end A for application of the adhesive 35 and the other end B for the application of the adhesive 35 may be configured so that they are not bonded together, but, rather, are intentionally shifted to provide an opening 40. In this manner, by providing an opening 40, it is possible to enable the gas present within the internal space to exit from the opening 40 when pressure is applied to the affixing surfaces. Moreover, the opening 40 is configured so that when the gap G between the affixing surfaces reaches the target value, the ends A and B of the adhesive 35 are automatically bonded together because of spreading of the adhesive 35 to seal the internal space. Then, by irradiating ultraviolet light to cure the adhesive 35, the element surface of the display substrate 33 can be completely sealed.

However, in this method, if the ends A and B of the adhesive 35 are not reliably and automatically bonded together when the gap G has reached the target value after the affixing surfaces are pressed towards each other, it is not possible to completely seal the element surface of the display substrate 33. Therefore, when this method is employed, it is necessary to use an adhesive having a high viscosity and to precisely control the amount and position of the adhesive.

If the control is not precise, the ends A and B of the adhesive 35 may be automatically bonded to each other before the pressing of the affixing surfaces is completed and, should this occur, pressurized gas would be sealed and remain within the sealed space and it may not be possible to press the substrates until the gap G between the affixing surfaces reaches the target value, or a portion of the sealing section may open because of the application of pressure and, thus, the sealing quality of the element surface of the display substrate 33 may not be secured.

On the other hand, even when the ends A and B of the adhesive 35 are automatically bonded when the gap G has reached the target value, if a seal line width W equivalent to that of the other sealing sections cannot be obtained at the bonding section, it is difficult to maintain the sealing quality for a long period of time.

### SUMMARY OF THE INVENTION

The present invention was conceived to solve the above problems, and an object of the present invention is to more stably seal a display substrate onto which an EL element is formed.

In order to achieve at least this object, according to one aspect of the present invention, there is provided a method for manufacturing an electroluminescence display device in which an element substrate and a sealing substrate are affixed via an adhesive therebetween, wherein an electroluminescence element is formed on a display region of the element substrate, the sealing substrate is placed to oppose the element substrate at the side onto which the element is formed, the adhesive is applied at positions to surround the formation region of the element, and the adhesive is cured, wherein the adhesive is applied to surround the element formation region such that an opening is provided for maintaining communication with outside when the element substrate and the sealing substrate are affixed via the adhesive therebetween and are pressed to achieve a predetermined gap between the substrates and, after the adhesive is applied, the element substrate and the sealing substrate are affixed via the adhesive therebetween and pressed.

In this manner, in the pattern of application of adhesive to surround the element formation region, an opening for maintaining communication with outside during the affixing process is formed. Therefore, when the substrates are pressed by, for example, affixing the element substrate and the sealing substrate and applying a pressure to the element substrate towards a fixed sealing substrate, a path for communication between the internal space and the outside can be maintained through the opening and, thus, it is possible to prevent the pressure of the internal space from becoming relatively higher than the outside pressure. In addition, because the gas in the internal space can be exhausted out from the internal space through the opening, it is possible to quickly and precisely perform the operation for affixing the substrates, pressing the substrates, and achieving a predetermined gap between the substrates. Moreover, it is easy to prevent any local variation in the contact width between each of the substrates and the adhesive for sealing the substrates.

According to another aspect of the present invention, it is preferable that, in the method for manufacturing, after the element substrate and the sealing substrate are pressed to achieve the predetermined gap and the applied adhesive is cured, the opening is closed.

According to another aspect of the present invention, it is preferable that, in the method for manufacturing, an adhesive for an opening (opening adhesive), being an identical material as the first adhesive is applied to the opening and is cured to close the opening.

In this manner, the closure of the opening is performed in a step after and separate from the curing of adhesive, allowing for quick and precise affixing and adhering process between the substrates. As described as an example, by using, for the opening adhesive, a material identical to that used for adhering between the substrates, applying the opening adhesive into the opening, and closing the opening, a high compatibility between the adhesives can be achieved after the closure, thereby preventing possible detachment between the opening adhesive and the adhesive surrounding the element formation region. In this manner, it is possible to preferably inhibit intrusion of impurities such as moisture into the sealed space.

According to another aspect of the present invention, it is preferable that, in the method for manufacturing, the temperature of the opening adhesive is controlled in the period before the opening adhesive is cured.

According to another aspect of the present invention, it is preferable that, in the method for manufacturing, the temperature of the opening adhesive is controlled so that the viscosity of the opening adhesive is such that the opening adhesive is able to infiltrate into the opening.

In this manner, by controlling the temperature of the opening adhesive, it is possible to easily and reliably fill the opening with the adhesive, even when the adhesive is one which has a high viscosity at a room temperature and which cannot readily be filled into a narrow region such as the opening. Thus, the quality of closure of the opening can be improved while a quicker process for closing the opening is also enabled.

According to another aspect of the present invention, it is preferable that, in the method for manufacturing, the adhesive is an ultraviolet curable resin, for example, a cation polymerizing, ultraviolet curable resin.

According to another aspect of the present invention, it is preferable that, in the method for manufacturing, a material of an ultraviolet curable resin which is identical to the material for the adhesive is applied to the opening and cured to close the opening.

According to another aspect of the present invention, it is preferable that, in the method for manufacturing, the temperature of an opening adhesive applied to said opening is controlled until said opening adhesive is cured so that the viscosity of said opening adhesive is such that said opening adhesive is able to infiltrate into said opening.

In this manner, by adhering the element substrate to the sealing substrate using an ultraviolet curable resin and closing the opening using a similar ultraviolet curable resin, it is possible to inhibit adverse effects on the elecroluminescence element during the curing of the adhesive. Especially, the characteristics of an organic electroluminescence element are likely to be degraded when the element is exposed to a high temperature. Because of this, it is possible to produce a highly reliable electroluminescence display device. Moreover, although many known ultraviolet curable resins have a high viscosity at around room temperature, by controlling the temperature of such a resin adhesive, by heating, for example, it is possible to sufficiently reduce the viscosity and to perform the sealing process quickly and precisely.

According to another aspect of the present invention, there is provided a method for manufacturing an electroluminescence display device in which a mother element substrate and a sealing substrate are affixed via an adhesive therebetween, wherein the mother element substrate comprises a plurality of element substrate regions onto each of which an electroluminescence element is formed in a display region, the sealing substrate is placed to oppose the mother element substrate at the side onto which the element is formed, and the adhesive is applied at positions to surround the formation region of the element; the adhesive is cured; the adhesive is applied to surround the element formation region within each element substrate region such that an opening is provided for maintaining communication with outside when the mother element substrate and the sealing substrate are pressed with the adhesive therebetween to achieve a predetermined gap between the substrates; after the adhesive is applied, the mother element substrate and the sealing substrate are affixed via the adhesive therebetween and pressed and the adhesive is cured; and, after the adhesive is cured, the mother element substrate and the sealing substrate which are adhered to each other are trimmed (cut) and separated into element substrate regions such that the opening of the adhesive formed in each element substrate region is exposed on a cutting surface.

In this manner, by forming a plurality of element substrate regions on a mother element substrate and separating them into individual element substrate regions after affixing the mother element substrate and a sealing substrate, a plurality of display panels can be manufactured efficiently and easily. In addition, by applying the adhesive in a pattern such that an opening remains when the substrates are affixed and in a manner to surround each element formation region and curing the adhesive, it is possible to affix and adhere the substrates without variations among the element substrate regions. Moreover, in the step for separating into each element substrate region after the adhesive is cured, by cutting such that the opening is exposed at the separating and cutting surface, it is possible to reliably and quickly perform the closing process of the opening.

Furthermore, when a water-repelling liquid such as a silicone oil is filled into the internal space, in the step for cutting and separating into individual element substrate regions, by exposing the opening at the cutting surface, it is possible to easily execute the filling process of the water-repelling liquid from the opening into the internal space.

### BRIEF DESCRIPTION OF THE DRAWINGS

FIG. 1 is a diagram for explaining sealing of a glass substrate with a sealing glass according to a method for manufacturing an EL display panel in a related art.

FIG. 2 is a schematic diagram showing an enlarged cross section when the glass substrate and sealing glass are affixed.

FIG. 3 is a plan view showing example sealing defects in a method for manufacturing an EL display device according to a related art.

FIG. 4 is an explanatory diagram showing an example device structure for practicing a first embodiment of a method for manufacturing an EL display device according to the present invention.

FIG. 5 is an explanatory diagram showing an example application shape of adhesive on the sealing glass according to the first embodiment.

FIG. 6 is a flowchart showing the steps in the process for sealing the element surface of the display substrate with a sealing glass according to the first embodiment.

FIG. 7 is an explanatory diagram showing an exterior appearance of a panel structure according to the first embodiment.

FIG. 8 is a schematic plan view showing an example structure of an element layer of an organic EL display panel.

FIGS. 9A and 9B are schematic cross sectional diagrams of an organic EL display panel along respective lines D-D and E-E of FIG. 8.

FIG. 10 is an explanatory diagram schematically showing an example device structure for filling the internal space of a panel structure with a silicone oil according to a second embodiment of a method for manufacturing an EL display panel according to the present invention.

FIG. 11 is a flowchart showing steps in the process for sealing the element layer of the display substrate with a sealing glass according to the second embodiment.

### DESCRIPTION OF PREFERRED EMBODIMENTS

### First Embodiment

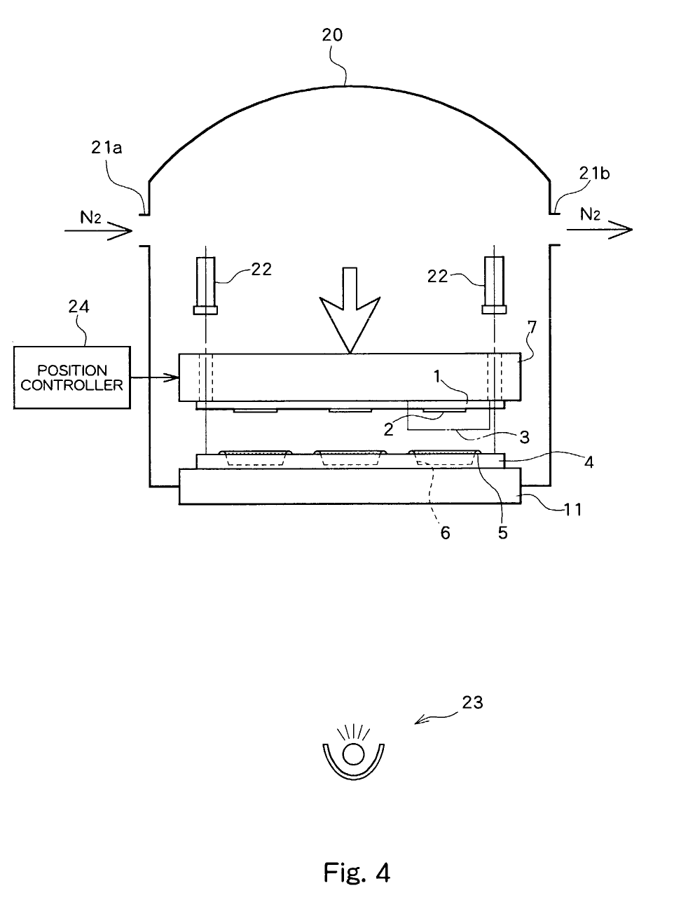

A first preferred embodiment of a method for manufacturing an EL display panel according to the present invention will now be described referring to FIGS. 4-7 using an example in which the method is used for manufacturing an EL display panel constructed to include an organic EL element. In the first embodiment, similar to the conventional art exemplified above, a display substrate (element substrate) onto which an organic EL element is formed is sealed by affixing the glass substrate and a sealing member (in the embodiments, glass; hereinafter referred to as “sealing glass”) with an adhesive.

FIG. 4 is a schematic diagram showing an example structure of an apparatus for manufacturing an EL display panel by the method for manufacturing according to the first embodiment.

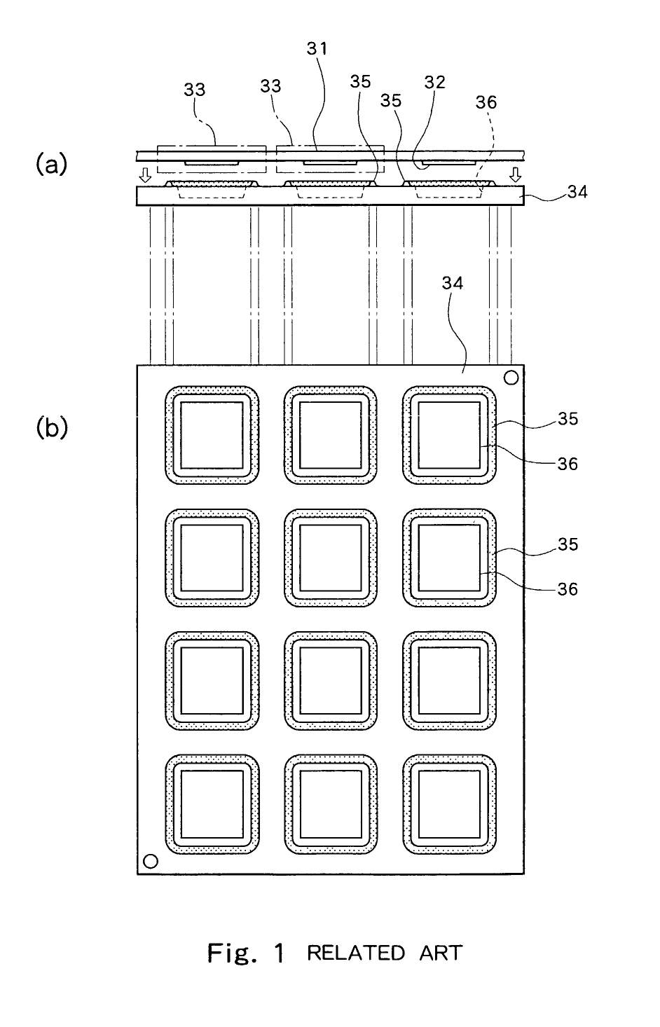

As shown in FIG. 4, on one surface of glass substrates 1 which are a type of a display substrate 3, element layers 2 constructed from an organic EL element or the like are formed through a thin film formation process. Again, in this structure, similar to FIG. 1, for example, a plurality of element layers 2 are simultaneously formed on a glass substrate 1 (mother substrate) and a plurality of display substrates 3 are simultaneously created so that a plurality of display panels are manufactured simultaneously. The glass substrate 1 is affixed (adhered) to a sealing glass 4, which is a sealing member placed to oppose the element layers 2. On the sealing glass 4, an adhesive 5 is applied in a manner to surround the display substrate 3, that is, along the shape for sealing the element layers 2. The adhesive 5 is made of an ultraviolet curable resin having a high viscosity, for example, a cation polymerizing, ultraviolet curable epoxy resin. The epoxy resin is well suited for an application to seal the organic EL element or the like because the resin has characteristics of low contraction ratio during curing process and low permeability for water. In addition, the surface of the sealing glass 4 which opposes the display substrate 3 is engraved through etching or the like to correspond to the shape and arrangement of the display substrates 3 (more specifically, their element layers 2). The engraved section 6 of the sealing glass 4 is provided for applying an absorbent or the like for maintaining the characteristics of the display substrate 3 to be sealed.

Each of the above described members is placed in a chamber 20. The inside of the chamber 20 is filled with nitrogen gas (N₂) which is supplied to and discharged from the chamber 20 through a respective gas introduction port 21a and gas discharging port 21b. In order to prevent degradation of the organic EL element formed on the display substrate 3 by the moisture present in the atmosphere, nitrogen gas having a moisture content of 5 ppm or less is used.

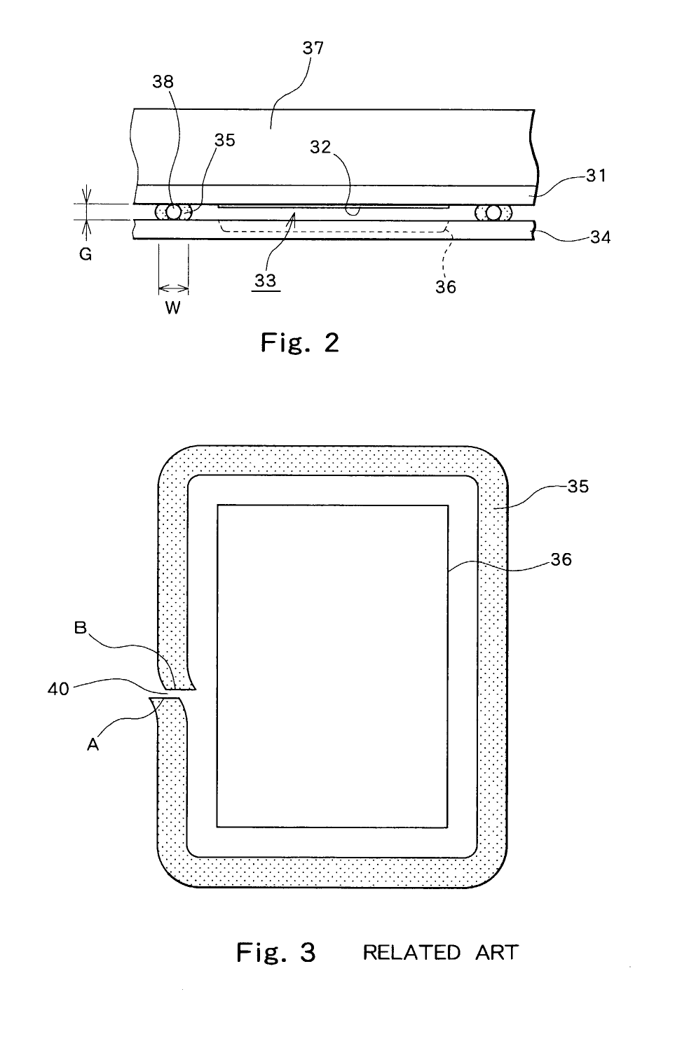

In the chamber 20, the glass substrate 1 is vacuum suctioned to a supporting member 7 provided within the chamber 20. The position of the supporting member 7 is controlled. In FIG. 4, the apparatus (mechanism) for vacuum suctioning the glass substrate 1 is not shown. On the other hand, the sealing glass 4 is placed on a quartz glass 11 which is installed at the bottom surface of the chamber 20. An apparatus 24 for controlling the position of the supporting member 7 moves the supporting member 7 and the glass substrate 1 in the horizontal direction based on an image of, for example, one or more positioning marks (not shown) which are imaged by one or more CCD cameras 22 provided within the chamber 20, and determines the relative position of the supporting member 7 and the glass substrate 1 with respect to the sealing glass 4. After the positioning process is completed, the supporting member 7 is lowered to press the glass substrate 1 towards the sealing glass 4 so that pressure is applied at the affixing surfaces of the glass substrate 1 and the sealing glass 4. In the manufacturing apparatus shown in FIG. 4, the reference numeral 23 denotes an ultraviolet light source for irradiating ultraviolet radiation through the quartz glass 11 and the sealing glass 4 onto the adhesive 5 composed of the cation polymerizing, ultraviolet curable epoxy resin, for curing the adhesive 5. In order to achieve a target gap value through application of pressure to the affixing surface, a spacer having an appropriate shape, such as, for example, a cylindrical shape with a diameter equal to the target value, is mixed within the adhesive 5 (refer to FIG. 2). After a sufficient pressure is applied to the affixing surface, the spacer functions as a stopper to allow the gap G to reach the target value.

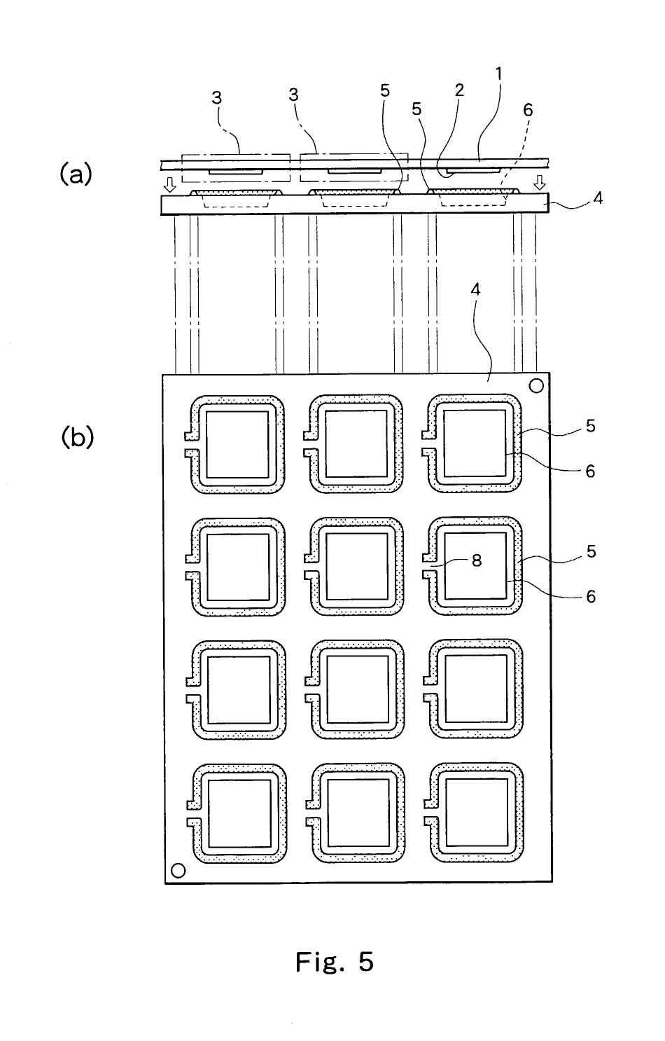

FIG. 5 is an explanatory diagram showing an example pattern of application of the adhesive 5 on the sealing glass 4. As shown in FIG. 5, the adhesive 5 is applied in such a manner as to surround the display region which is the element surface of the display substrate when the sealing glass 4 and the glass substrate 1 are affixed, and the application shape includes an opening 8 through which the space for sealing the element surface of each display substrate 3 communicates with the outside when the substrates are affixed. An engraved section 6 is provided to oppose the element surface of the display substrate 3.

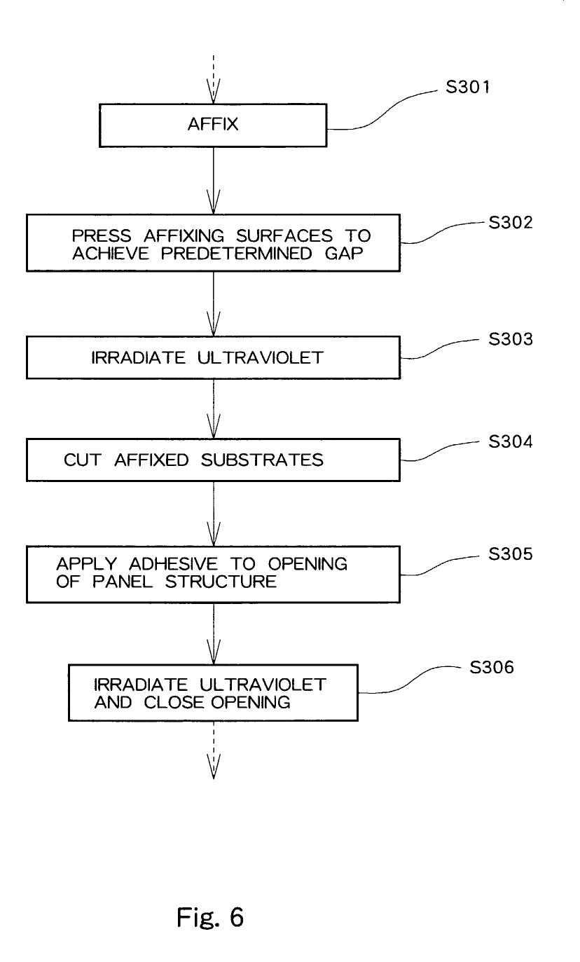

With the above structure, the sealing of the element surface of the display substrate 3 with the sealing glass 4 is performed as follows, as shown in a flowchart of FIG. 6.

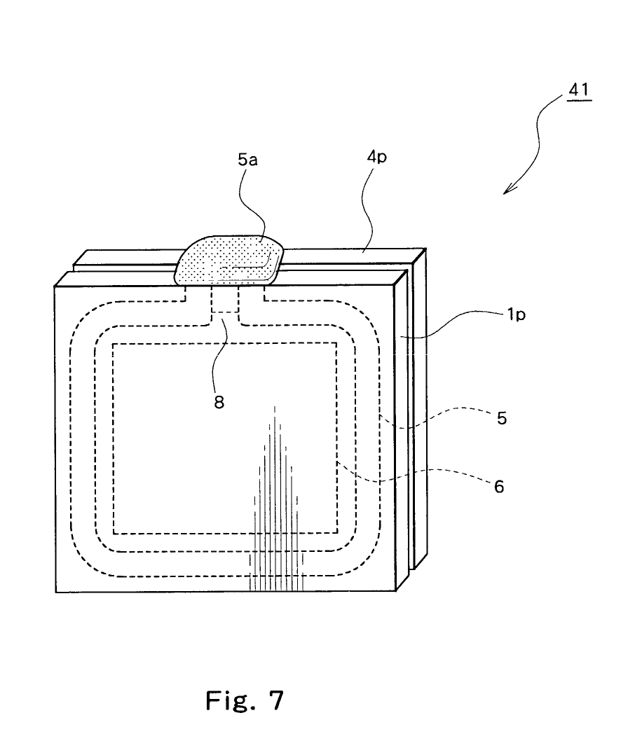

First, the supporting member 7 to which the glass substrate 1 is held through vacuum suction is lowered to affix the glass substrate 1 over the sealing glass 4 onto which the adhesive 5 is applied in a shape to include an opening 8 as shown in FIG. 5 (step S301). Then, the supporting member 7 applies an appropriate pressure to the affixing surface to press the glass substrate 1 until the gap G between the affixing surfaces of the glass substrate 1 and the sealing glass 4 reaches a target value (step S302). During this process, the nitrogen gas present within the space surrounded by the glass substrate 1, sealing glass 4, and adhesive 5 is preferably discharged to the outside via the opening 8. Therefore, even after a target gap G is achieved by affixing the substrates, the element surface of the glass substrate 1 is not completely sealed with the sealing glass 4 and the adhesive 5. The pressure of the internal space is held equal to the ambient pressure, that is, the pressure of nitrogen gas within the chamber 20 (in this example, atmospheric pressure) because an opening 8 is provided for the adhesive 5. Next, while the application of pressure to the affixing surface is continued and the gap G is held at the target value, the ultraviolet light source 23 is switched on to start irradiating the adhesive 5 with ultraviolet light through the quartz glass 11 and the sealing glass 4, to cure the adhesive 5 (step S303). In this manner, the gap G between the glass substrate 1 and the sealing glass 4 is fixed at the target value and the affixing (adhering) of the glass substrate 1 and the sealing glass 4 is completed. Then, the affixed substrates are cut into a shape such that each element layer 2 formed on the display substrate 3 is individually sealed and are separated into affixed substrates (panel structures) 41 to be used for individual panel as shown in FIG. 7 (step S304). In this step, the affixed substrates are cut so that the opening 8 of the adhesive applied to each display substrate 3 lines up with the end of the cutting surface of the panel structure 41. Then, an adhesive identical to that used for affixing is applied to the opening 8 of the affixing surface of the panel structure 41 (step S305). The application of adhesive 5a to the opening 8 is performed, as shown in FIG. 7, by placing the panel structure 41 such that the opening 8 of the panel structure 41 faces upwards, applying the adhesive 5a from a dispenser (not shown) onto the opening 8, and allowing the applied adhesive 5a to infiltrate from the end of cutting surface through its own weight, to fill at least the entrance section of the opening 8. For application of the adhesive 5a, in some cases the viscosity of the adhesive 5a to be used may be significantly high at room temperature. In this case, in order to obtain an appropriate viscosity for the adhesive 5a applied to the end of cutting surface to fill the opening 8 of the panel structure 41, the adhesive in the dispenser is warmed. Alternatively, the adhesive may be warmed after the application of the adhesive. Next, the adhesive 5a is irradiated with ultraviolet light and is cured, in order to close the opening 8 of the panel structure 41. Thus, the element surface of the display substrate 3 separated for each panel is completely sealed (step S306). It is preferable that the processes in the above steps S304-S306 be performed in an atmosphere having low moisture content and composed of an inert gas such as, for example, nitrogen, similar to the steps S301-S303 as described above, in order to inhibit degradation in characteristics of the organic EL element. Also, in steps S303 and S306, in order to prevent heating of the organic EL element having a low thermal endurance and degradation in characteristics thereof by the infrared component of the light by the ultraviolet light source 23, it is desirable to pass the light through an infrared filter before irradiating the adhesive. It is further desirable either not to emit ultraviolet light components that do not transmit through the glass substrate 4, or, alternatively that these ultraviolet light components be absorbed by the glass substrate 4.

For reference, an example structure of an element layer 2 formed on the display substrate 3 which is used as the organic EL display panel will now be described.

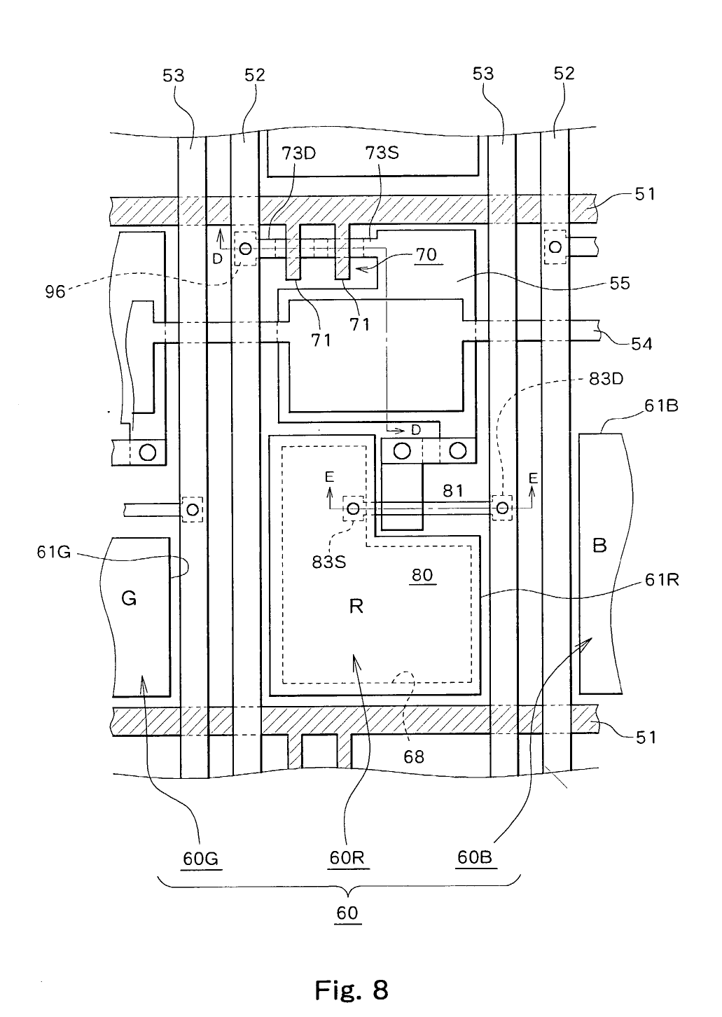

FIG. 8 is an enlarged plan view of a pixel and its periphery of an active matrix type EL display panel in which a thin film transistor (TFT) which is an active element is added for each EL element forming a display unit (pixel) of the display device.

The EL display panel is a display device which takes advantage of the property of an EL element which emits light when an electric field is applied. On a display substrate, gate signal lines for driving switching TFTs and signal lines for allowing display of each pixel are formed in rows and columns in a matrix form.

As shown in FIG. 8, in the EL display panel, gate signal lines 51 and drain signal lines 52 are formed as the signal lines as described above. Organic EL elements 60 are formed as pixels corresponding to the intersections of these signal lines. In the EL display panel, in order to realize a full-color display, repeating units are formed each consisting of three types of organic EL elements 60R, 60G, and 60B having different emission colors. These three types of EL elements form a group to constitute a display unit as a full-color display device for emitting light of a desired color.

In the vicinity of an intersection between the signal lines, a TFT 70 which is switched by the gate signal line 51 is formed. When the TFT 70 is switched “ON”, the signal on the drain signal line (data signal line) 52 is connected to the source 73S and applied to a capacitor electrode 55. The capacitor electrode 55 is connected to a gate 81 of a TFT 80 for driving an EL element. The source 83S of the TFT 80 is connected to an anode 61 of the organic EL element 60 and the drain 83D of the TFT 80 is connected to the driving power supply line 53 which functions as an electric current source for supplying electric current to the organic EL element 60.

Corresponding to the TFTs 70 and 80, a storage capacitor electrode line 51 is formed parallel to the gate signal line 51. The storage capacitor electrode line 54 is formed of, for example, a metal such as chromium (Cr), similar to the gate signal line 51. The storage capacitor electrode line 54 and the capacitor electrode 55 which is placed to oppose the storage capacitor electrode line 54 with an insulative film in between constitute a capacitor element (storage capacitor) in which charges are accumulated. The storage capacitor is provided for maintaining the voltage applied to the gate electrode 81 of the TFT 80.

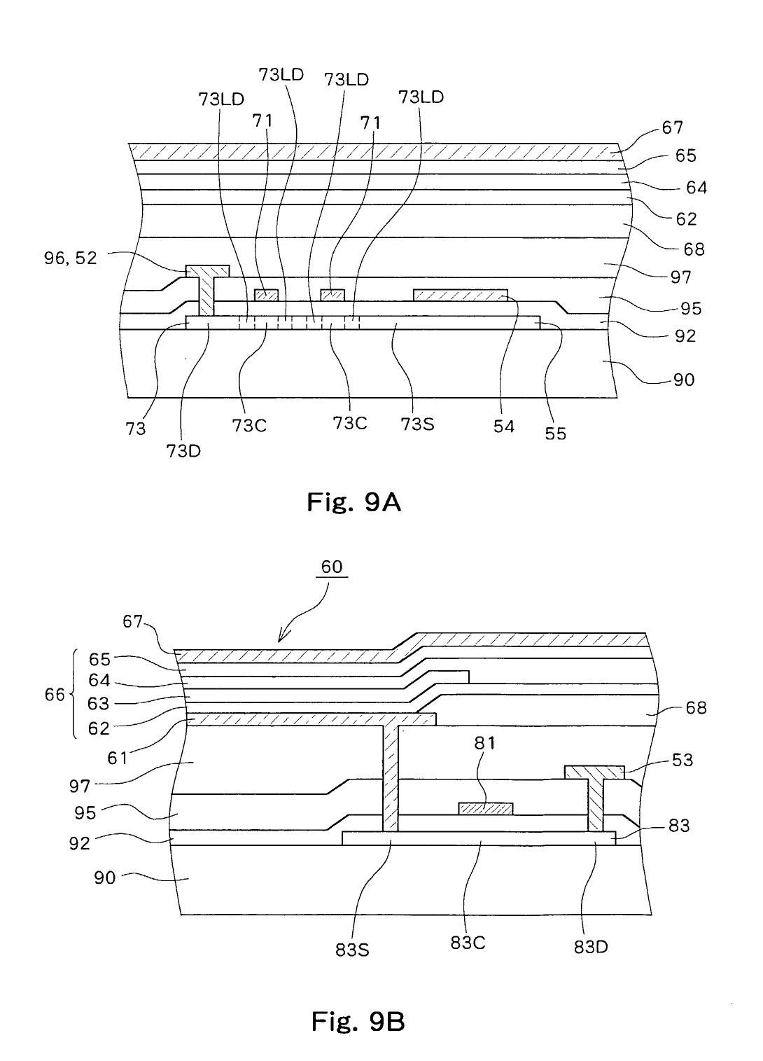

FIGS. 9A and 9B show cross sections near the pixel shown in FIG. 8. FIG. 9A shows a cross section along the line D-D in FIG. 8 and FIG. 9B shows a cross section along the line E-E in FIG. 8. As shown in FIGS. 9A and 9B, the element layer of the display substrate in the organic EL display panel is formed by sequentially layering the TFT and the organic EL element 60 on substrate 90 such as a glass substrate, a synthesized resin substrate, a conductor substrate, or a semiconductor substrate.

The formation process of the TFT 70 for controlling the charging/discharging of the capacitor electrode 55 will first be described.

As shown in FIG. 9A, on an insulative substrate 90 made of quartz glass, non-alkali glass, or the like, an active layer 73 is formed which is made of a polycrystalline silicon film obtained by polycrystallizing an amorphous silicon film through irradiation of laser. In the active layer 73, a structure commonly known as an LDD (Lightly Doped Drain) structure is created. More specifically, on both sides of the channel, low concentration regions 73LD are provided, and further a source 73S and a drain 73D which are high concentration regions are provided outside the LD region 73LD. Over the active layer 73, a gate insulative film 92 and a gate electrode 71 which constitute a portion of the gate signal line 51 made of a high melting point metal such as Cr and molybdenum (Mo) are formed. At the same time, the storage capacitor electrode 54 is also formed. Then, an interlayer insulative film 95 having a structure in which a silicon oxide film (SiO₂ film) and a silicon nitride film (SiN film) are layered in that order is formed over the entire surface of the gate insulative film 92. A contact hole is formed to correspond to the drain 73D and is filled with a metal such as aluminum (Al). The drain signal line 52 and a drain electrode 96 which forms a part of the drain signal line 52 are then formed. Over the film surface, a planarization insulative film 97 is provided for planarizing the surface, the film 97 being made of, for example, an organic resin.

Next, the formation process of the TFT 80 for driving the organic EL element 60 to emit light will be described. In FIG. 9B, structures formed of the same material as, and simultaneously with, the structures described above with reference to FIG. 9A are generally assigned the same reference numerals.

As shown in FIG. 9B, on the insulative substrate 90 as described above and made of quartz glass, non-alkali glass, or the like, an active layer 83 made of the polycrystalline silicon film is formed simultaneously with the active layer 73 of the TFT 70. In the active layer 83, a channel 83C which is intrinsic or substantially intrinsic is provided below the gate electrode 81 and a source 83S and a drain 83D are provided at both sides of the channel 83C by ion doping a p-type impurity, so that a p-type channel TFT is formed. Over the active layer 83, the gate insulative film 92 and the gate electrode 81 made of a high melting point metal such as Cr and Mo are formed. The gate electrode 81 is formed simultaneously with the gate electrode 71 in FIG. 9A, and is connected to the source 73S of the TFT 70 as described above. Over the entire surface of the gate insulative film 92 and the gate electrode 81, an interlayer insulative film 95 is formed in which a SiO₂ film and a SiN film are layered in that order. A contact hole is formed to correspond to the drain 83D and is filled with a metal such as Al. At the same time, the driving power supply line 53 is formed. Furthermore, over the film surface, a planarization insulative film 97 is formed for planarizing the surface, the film 97 being made of, for example, an organic resin. A contact hole is formed in the planarization insulative film 97 to allow a connection to the source 83S and a transparent electrode 61 which is to be connected to the source 83S through the contact hole is formed on the planarization insulative film 97. The transparent electrode 61 constitutes the anode of the organic EL element, and allows transmission, towards the side of the substrate 90, of light emitted from the organic EL element 60 to be layered on top of the transparent electrode 61. As the transparent electrode 61, for example, an ITO (Indium Tin Oxide) which is an oxide of indium and tin is used.

The organic EL element 60 is constructed by forming and layering a light emitting element layer 66 and an Al cathode 67 in that order on top of the anode 61. The light emitting element layer 66 further has a four-layer structure, each structure formed and layered above the anode 61 in order and made of a material, for example, as described below.

(1) Hole transport layer 62: “NPB”

(2) Emissive layer 63: following materials are used corresponding to each of different emission colors

Red—A host material “Alq₃” doped with “DCJTB”

Green—A host material “Alq₃” doped with “coumarin 6”

Blue—A host material “BAlq” doped with “perylene”

(3) Electron transport layer 64: “Alq₃”

(4) Electron injection layer 65: lithium fluoride (LiF)

The abbreviations used above for describing the materials represent the following compounds.

“NPB”—N,N′-di(naphthalene-1-yl)-N,N′-diphenyl-benzidine

“Alq₃” Tris(8-hydroxyquinolinato)aluminum

“DCJTB”

(2-(1,1-dimethylethyl)-6-(2-(2,3,6,7-tetrahydro-1,1,7,7-tetram ethyl-1H,5H-benzo[ij]quinolizin-9-yl)ethenyl)-4H-pyran-4-ylide ne)propanedinitrile

“Coumarin 6”—3-(2-benzothiazolyl)-7-(diethylamino)coumarin

“BAlq”—(1,1′-bisphenyl-4-olato)bis(2-methyl-8-quinolinplate-N1,08)aluminum

The hole transport layer 62, electron transport layer 64, electron injection layer 65, and cathode 67 are formed to be common for each of the organic EL elements 60 corresponding to a pixel as shown in FIG. 8. An island-like emissive layer 63 is formed corresponding to the anode 61. At the periphery of the anode 61, an insulative film (planarization insulative film) 68 made of an organic resin or the like is formed (outside the region shown by dotted lines in FIG. 8). This film is provided in order to prevent shortage of the cathode 67 and anode 60 caused by cracking of the emissive layer 63 due to the step created by the thickness of anode 61.

When the pixel of the organic EL element 60 formed as described above is driven by the TFTs 70 and 80, holes injected from the anode 61 and the electrons injected from the cathode 67 are recombined within the emissive layer 63 and light is emitted.

When the above materials are used for each of the layers constituting the organic EL element 60, it is preferable to set the temperature that can be applied to the element layer 2 to 95° C. or less, in order to prevent degradation of characteristics of each layer.

As described, the following advantages can be obtained through a method for manufacturing an EL display panel according to the first embodiment.

(1) When the adhesive 5 is applied to the affixing surface when the glass substrate 1 and the sealing glass 4 are affixed, an opening 8 is provided in the application pattern of the adhesive 5, the opening 8 having a sufficient width such that even if the adhesive 5 is spread due to the application of pressure to the affixing surface, the adhesive 5 would not automatically and completely surround the display region. Because of this, the sealed internal space is connected to the outside via the opening 8 during the affixing process, and therefore the gas within the internal space does not create a barrier, allowing for the gap G to easily, smoothly, and quickly reach a target value when the affixing surface is pressed.

(2) When achieving a target value for the gap G of the affixing surfaces, the gas within the internal space of the affixed substrate 41 can be reliably discharged to the outside in response to the application of pressure to the affixing surface. Because of this, it is possible to easily apply pressure to the affixing surface to smoothly achieve a target gap G between the affixing surfaces, and to stably obtain a precise seal line width W.

(3) Because no pressurized gas is sealed within the sealed space when the sealing is completed and the occurrence frequency of sealing defects during the affixing process is reduced, the long-term sealing quality can be improved.

(4) When the glass substrate 1 and the sealing glass 4 are affixed and a pressure is applied, it is not necessary to automatically bond the ends of the applied adhesive 5 by spreading. Because of this, when the adhesive 5 is applied on the sealing glass 4, the required precision for the positions of the application starting point and end point, the amount of application, etc., is not as strict.

(5) When the opening 8 is closed, it is possible to adjust the viscosity of the adhesive 5a to a value suitable for penetration through the opening 8 by appropriately raising the temperature of the adhesive 5a regardless of whether the display element's strength or vulnerability to heat. It is therefore possible to more easily and more reliably close the opening 8 to seal the element surface of the display substrate 3.

(6) In order to close the opening 8, an adhesive identical to the adhesive used for affixing the glass substrate 1 and the sealing glass 4 is applied to the opening 8 and then is cured. Because of this, it is possible to reliably close the opening without any additional components. Also, because the adhesive used for affixing and the adhesive used for closure are compatible, it is possible to improve the reliability of sealing at the contacting sections of the adhesive.

(7) Because the sealing quality at the sealing section that can be obtained through the process as described above is high, it is possible to manufacture an EL display panel which has small degradation of characteristics and is highly reliable as a display device.

### Second Embodiment

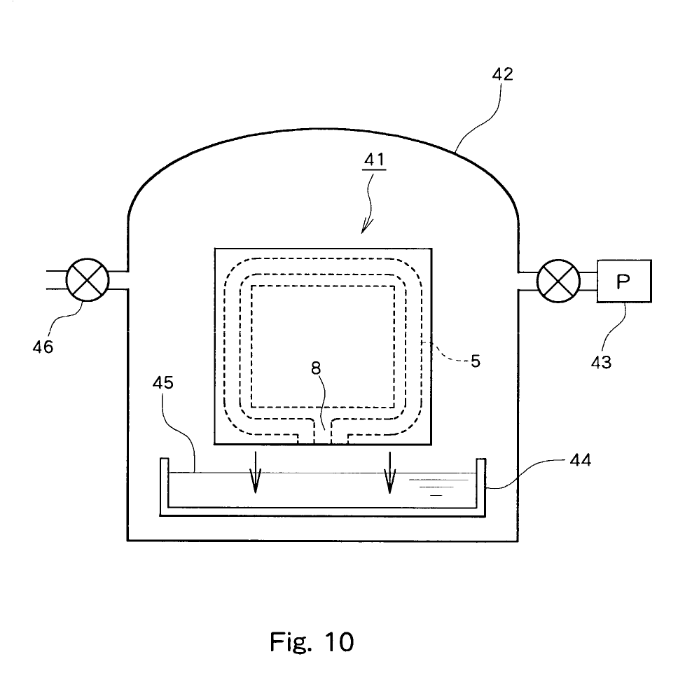

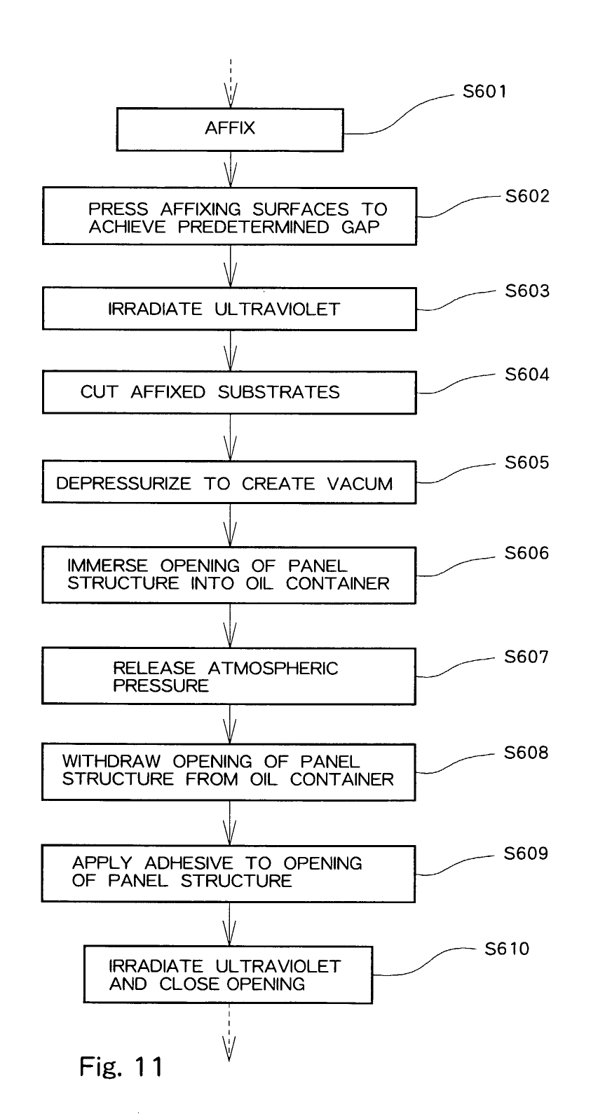

A method for manufacturing an EL display panel according to a second embodiment of the present invention will now be described referring to FIGS. 10 and 11. Similar as in the first embodiment, the second embodiment will be described using an example case in which the method is applied as a method for manufacturing an EL display panel constructed to include an organic EL element. In the following, the description focuses primarily on the structures differing from those of the first embodiment.

A method for manufacturing an EL display panel according to the second embodiment includes, in addition to the sealing process described in the first embodiment, a process for filling with, instead of the dry N₂ gas as described in the first embodiment, a water-repelling liquid as the fluid for filling the internal space of the panel structure 41, that is, the space for sealing the element surface of the display substrate 3. Because this liquid directly contacts the element layer 2 formed on the display substrate 3, it is preferable to use a material having low content of impurities such as moisture and is inert with respect to the element layer 2, such as, for example, a silicone oil.

FIG. 10 schematically shows an example device structure for filling a silicone oil into the space for sealing the element layer 2 of the display substrate 3.

As shown in FIG. 10, an apparatus for filling a silicone oil into the internal space of a panel structure 41 comprises a vacuum chamber 42, a vacuum pump 43, an oil container 46 supplied with silicone oil 45, and a valve 46 for breaking the vacuum within the vacuum chamber 42. In addition, although not shown in FIG. 10, one or more devices for transporting and/or supporting the panel structure 41 are also provided. The vacuum pump 43 is preferably a dry pump in order to prevent impurities from mixing into the chamber 42.

The above described apparatus is used in conjunction with the apparatus used for affixing the glass substrate 1 and sealing glass 4 as described in the first embodiment, to execute the sealing process based on the flowchart shown in FIG. 11 which shows an example procedure.

First, a glass substrate 1 and a sealing glass 4 are affixed with an adhesive such that an opening 8 remains (step S601). In the second embodiment, similar to the first embodiment, a cation polymerizing, ultraviolet curable epoxy resin is used as the adhesive. Then, pressure is applied to the affixing surface so that the gap G reaches a target value (step S602) and ultraviolet is irradiated to cure the adhesive (step S603). Next, the affixed substrates are trimmed (step S604) to obtain panel structures 41 each for sealing individually the element layer 2 of the display substrate. The steps until this point is basically identical to the steps S301-S304 shown in FIG. 6 and described for the first embodiment. Next, the panel structure 41 is introduced into the chamber 42 with the opening 8 facing downward, and the inside of the chamber 42 is depressurized using the vacuum pump 43 to create a vacuum of approximately 0.13 Pa (0.001 Torr) (step S605). Then, the opening 8 of the panel structure 41 is immersed into the oil container 44 which is filled with a high purity silicone oil 45 (step S606). Next, while the opening 8 of the panel structure 41 remains continuously immersed in the silicone oil 45, the valve 46 is gently opened to break the vacuum in the chamber 42 (step S607). With this process, the pressure within the chamber 42 becomes the atmospheric pressure and the internal space of the panel structure 41 is filled with silicone oil 45 by the atmospheric pressure. Following this step, the opening 8 of the panel structure 41 is withdrawn from the silicone oil 45 into which the opening 8 has been immersed (step S608 in FIG. 11). The silicone oil 45 attached to the panel structure 41 near the opening 8 is removed in order to prevent detachment of the adhesive. After this step, the process proceeds in a similar manner as steps S305 and S306 shown in FIG. 6 for the first embodiment. That is, while the opening 8 of the panel structure 41 continuously faces upward, an adhesive identical to the adhesive used in the affixing process is applied from a dispenser (not shown) (step S609) and ultraviolet light is irradiated onto the section to which the adhesive is applied so that the opening 8 is closed (step S610 in FIG. 11). During this process, in order to prevent degradation of characteristics of the organic EL element, it is desirable to employ a configuration such that the ultraviolet light is not irradiated onto the organic EL element. When a light-shielding metal electrode is employed as the cathode of the organic EL element and is formed as the topmost layer of the element, by irradiating the light from the side of the sealing substrate, the organic layer can be protected from the light by the light-shielding cathode. In the sequence of processes from step S604 to step S610, similar to the steps S601-S603, it is desirable to perform these steps in an atmosphere having small moisture content such as nitrogen gas in order to prevent degradation in characteristics of the element layer 2 formed on the display substrate 3.

In this manner, in the second embodiment, silicone oil 45 is filled into the internal space of the panel structure 41. As described, according to the method for manufacturing an EL display panel in the second embodiment, the following advantages can be obtained in addition to those that can be obtained through the first embodiment.

(8) Because the internal space for sealing the element surface of the display substrate 3 is depressurized to create vacuum and then high purity silicone oil 45 is filled, even if an impurity such as moisture permeates through the sealing section and enters the internal space, it is possible to reduce the opportunity for the impurity to be indirect contact with the element layer 2 through the water-repelling characteristic of the silicone oil.

(9) The degradation of characteristics of the organic EL element used as the light emitting material can be preferably inhibited and the display function as the display device can be maintained for even longer period of time.

### Other Embodiments

The above described embodiments can also be practiced with the following modifications.

In the examples of the above embodiments, an ultraviolet curable resin is used as the adhesive 5 for affixing the glass substrate land the sealing glass 4. However, the present invention is not limited to such a configuration, and the adhesive 5 may be a thermosetting resin or another adhesive which is cured by other means. The adhesive may also be an acrylic resin. As long as the adhesive can reliably affix the affixing surfaces and preferably seal the element surface of the display substrate 3 without causing degradation in the characteristics, any type of adhesive may be used.

In the above embodiments, nitrogen gas is used as the gas to fill inside the chamber 20. However, the present invention is not limited to such a configuration. As long as the gas is an inert gas that has low moisture content and does not adversely affect the display substrate 3, any gas, for example, a noble gas such as Ar, can be used in place of the nitrogen gas.

In the above embodiments, an example EL display panel is shown in which a display substrate 3 onto which an organic EL element is formed is sealed. However, the present invention is not limited to such a configuration. For example, the method according to the present invention can be applied for sealing a display substrate onto which an inorganic EL element is formed as a light emitting element.

In the above embodiments, a sealing glass 4 is used as the sealing member for sealing the element surface of the display substrate 3. However, the present invention is not limited to such a configuration. For example, the element surface of the display substrate 3 may be sealed using a metal casing (metal can).

In the second embodiment, the chamber 20 used in the process for affixing the glass substrate 1 and the sealing glass 4 and the chamber 42 for filling the internal space of the panel structure 41 with the silicone oil 45 are described as separate structures. However, a common chamber may be used for both purposes.

In the example illustrating the second embodiment, a high purity silicone oil 45 is used as the fluid for filing the internal space of the panel structure 41. However, the present invention is not limited to such a configuration, and any fluid having a water-repelling characteristic and which does not degrade the characteristics of the element layer 2 formed on the display substrate 3 can be used.

What is claimed is:

1. A method for manufacturing an electroluminescence display device in which an element substrate and a sealing substrate are affixed via an adhesive therebetween, wherein:
an electroluminescence element is formed on a display region of said element substrate, said sealing substrate is placed to oppose said element substrate at the side onto which said element is formed, said adhesive is applied at positions to surround the formation region of the element, and said adhesive is cured;
said adhesive is applied to surround said element formation region such that an opening is provided for maintaining a connection with the outside when said element substrate and said sealing substrate are affixed via said adhesive therebetween and are pressed to achieve a predetermined gap between said substrates; and
after said adhesive is applied, said element substrate and said sealing substrate are affixed via said adhesive therebetween and pressed.

2. A method for manufacturing an electroluminescence display device according to claim 1, wherein
after said element substrate and said sealing substrate are pressed to achieve said predetermined gap and said applied adhesive is cured, said opening is closed.

3. A method for manufacturing an electroluminescence display device according to claim 2, wherein
an opening adhesive identical to the adhesive between the element substrate and the sealing substrate is applied to said opening and is cured to close said opening.

4. A method for manufacturing an electroluminescence display device according to claim 3, wherein
the temperature of said opening adhesive is controlled in the period before said opening adhesive is cured.

5. A method for manufacturing an electroluminescence display device according to claim 4, wherein
the temperature of said opening adhesive is controlled so that the viscosity of said opening adhesive is such that said opening adhesive is able to infiltrate into said opening.

6. A method for manufacturing an electroluminescence display device according to claim 1, wherein
said adhesive is an ultraviolet curable resin.

7. A method for manufacturing an electroluminescence display device according to claim 6, wherein
an ultraviolet curable resin identical to said adhesive is applied to said opening and cured to close said opening.

8. A method for manufacturing an electroluminescence display device according to claim 1, wherein
said adhesive is a cation polymerizing, ultraviolet curable resin.

9. A method for manufacturing an electroluminescence display device according to claim 8, wherein
the temperature of an opening adhesive applied to said opening is controlled until said opening adhesive is cured so that the viscosity of said opening adhesive is such that said opening adhesive is able to infiltrate into said opening.

10. A method for manufacturing an electroluminescence display device according to claim 1, wherein
after said element substrate and said sealing substrate are pressed to achieve a predetermined gap between said substrates and said applied adhesive is cured, a water-repelling liquid is filled into the space formed by said element substrate, said sealing substrate, and said cured adhesive, and said opening is closed.

11. A method for manufacturing an electroluminescence display device in which a mother element substrate and a sealing substrate are affixed via an adhesive therebetween, wherein:
said mother element substrate comprises a plurality of element substrate regions onto each of which an electroluminescence element is formed in a display region, said sealing substrate is placed to oppose said mother element substrate at the side onto which said element is formed, and said adhesive is applied at positions to surround the formation region of the element;
said adhesive is cured;
said adhesive is applied to surround the element formation region within each said element substrate region such that an opening is provided for maintaining communication with the outside when said mother element substrate and said sealing substrate are pressed with said adhesive therebetween to achieve a predetermined gap between said substrates;
after said adhesive is applied, said mother element substrate and said sealing substrate are affixed via said adhesive therebetween and pressed and said adhesive is cured; and
after said adhesive is cured, said mother element substrate and said sealing substrate which are adhered to each other are cut and separated into individual element substrate region such that said opening of said adhesive formed in each said element substrate region is exposed on a cutting surface.

12. A method for manufacturing an electroluminescence display device according to claim 11, wherein
after said step for cutting and separating, said opening exposed on the cutting surface is closed.

13. A method for manufacturing an electroluminescence display device according to claim 12, wherein
an opening adhesive identical to said adhesive is applied to said opening and is cured to close said opening.

14. A method for manufacturing an electroluminescence display device according to claim 13, wherein
the temperature of said opening adhesive is controlled in the period before said opening adhesive is cured.

15. A method for manufacturing an electroluminescence display device according to claim 14, wherein
the temperature of said opening adhesive is controlled so that the viscosity of said opening adhesive is such that said opening adhesive is able to infiltrate into said opening.

16. A method for manufacturing an electroluminescence display device according to claim 11, wherein
said adhesive is an ultraviolet curable resin.

17. A method for manufacturing an electroluminescence display device according to claim 16, wherein
a material of an ultraviolet curable resin which is identical to the material for said adhesive is applied to said opening and cured to close said opening.

18. A method for manufacturing an electroluminescence display device according to claim 11, wherein
said adhesive is a cation polymerizing, ultraviolet curable resin.

19. A method for manufacturing an electroluminescence display device according to claim 18, wherein
the temperature of an opening adhesive applied to said opening is controlled until said opening adhesive is cured so that the viscosity of said opening adhesive is such that said opening adhesive is able to infiltrate into said opening.

20. A method for manufacturing an electroluminescence display device according to claim 11, wherein
after said step for cutting and separating, a water-repelling liquid is filled into the space formed by said element substrate region, said sealing substrate, and said cured adhesive, and said opening exposed at said cutting surface is closed.

21. A method for manufacturing an electroluminescence display device according to claim 20, wherein said water-repelling liquid is a silicone oil.
